(19) United States
(12) Patent Application Publication
(10) Pub. No.: US 2024/0397783 A1
(43) Pub. Date: Nov. 28, 2024

(54) ELECTRONIC DEVICE AND METHOD FOR MANUFACTURING THE SAME

(71) Applicant: Samsung Display Co., LTD., Yongin-si (KR)

(72) Inventors: JEONGWEON SEO, Yongin-si (KR); JUNYOUNG LEE, Yongin-si (KR); YOUNGDO KIM, Yongin-si (KR); JUNWOO YOU, Yongin-si (KR)

(21) Appl. No.: 18/603,465

(22) Filed: Mar. 13, 2024

(30) Foreign Application Priority Data
May 26, 2023 (KR) 10-2023-0068668

(51) Int. Cl. H10K 59/65

(52) U.S. Cl. CPC H10K 59/65

(57) ABSTRACT

An electronic device includes a display panel including a first area and a second area adjacent to the first area, an electronic module overlapping the first area and disposed below the display panel, and a protective layer overlapping the second area and disposed below the display panel. The protective layer includes a base resin and a plurality of magnetic particles dispersed in the base resin, and a ratio of a weight of the plurality of magnetic particles to a total weight of the protective layer gradually increases from a bottom surface of the protective layer to a top surface of the protective layer.

This application claims priority to Korean Patent Application No. 10-2023-0068668, filed on May 26, 2023, the entirety of the contents of which are hereby incorporated by reference.

### BACKGROUND

### 1. Field

Embodiments of the disclosure relate to an electronic device and a method for manufacturing the same, and more particularly, to an electronic device with improved reliability and a method for manufacturing the electronic device.

### 2. Description of the Related Art

Electronic devices including display devices, such as smartphones, digital cameras, notebook computers, navigation devices and smart televisions, provide users with images through display screens.

A display device may include a display panel, which provides image information, and a protective layer for protecting the display panel from the outside. The protective layer prevents the display panel from being deformed due to an external impact, and effectively dissipates heat generated in the display panel to protect the display panel from the outside. In order to give various functions to protect the display panel, a structure in which a plurality of functional layers is stacked is applied to the protective layer.

Research is carried out on an electronic device, to which a single-layer protective layer having various integrated functions to protect the display panel is applied, and a method for manufacturing the electronic device.

### SUMMARY

The disclosure provides an electronic device with improved reliability and a method for manufacturing the electronic device.

An embodiment of the inventive concept provides an electronic device including a display panel including a first area and a second area adjacent to the first area, an electronic module overlapping the first area and disposed below the display panel, and a protective layer overlapping the second area and disposed below the display panel. The protective layer includes a base resin and a plurality of magnetic particles dispersed in the base resin, and a ratio of a weight of the plurality of magnetic particles to a total weight of the protective layer gradually increases from a bottom surface of the protective layer to a top surface of the protective layer.

In an embodiment, the protective layer may be disposed directly on a bottom surface of the display panel.

In an embodiment, the protective layer may have a thickness of about 100 micrometers (m) to about 500 m.

In an embodiment, the base resin may include a curable resin.

In an embodiment, each of the plurality of magnetic particles may include at least one of a heat dissipation material, a support material, or a shielding material.

In an embodiment, the plurality of magnetic particles may have an average diameter of about 5 m to about 100 m.

In an embodiment, a hole overlapping the first area may be defined in the protective layer, and at least a portion of the electronic module may be disposed inside the hole.

In an embodiment, the protective layer may include a first portion disposed below the display panel, and a second portion disposed below the first portion. The first portion may include a first base resin and a plurality of first magnetic particles dispersed in the first base resin, and the second portion may include a second base resin and a plurality of second magnetic particles dispersed in the second base resin. A ratio of a weight of the plurality of first magnetic particles to a total weight of the first portion may be higher than a ratio of a weight of the plurality of second magnetic particles to a total weight of the second portion.

In an embodiment, the first base resin may include the same material as that of the second base resin.

In an embodiment, a density of the plurality of first magnetic particles may be higher than a density of the plurality of second magnetic particles.

In an embodiment, the protective layer may further include a third portion disposed below the second portion, and the third portion may include a third base resin and cover the plurality of second magnetic particles.

In an embodiment, the third base resin may include the same material as that of the first base resin and the second base resin.

In an embodiment of the inventive concept, an electronic device includes a display panel including a first area and a second area adjacent to the first area, and a protective layer overlapping the second area and disposed below the display panel. The protective layer includes a first portion disposed below the display panel, and a second portion disposed below the first portion. The first portion includes a first base resin and a plurality of first magnetic particles dispersed in the first base resin, and the second portion includes a second base resin and a plurality of second magnetic particles dispersed in the second base resin. A ratio of a weight of the plurality of first magnetic particles to a total weight of the first portion is higher than a ratio of a weight of the plurality of second magnetic particles to a total weight of the second portion.

In an embodiment of the inventive concept, a method for manufacturing an electronic device includes providing a display panel including a first area and a second area adjacent to the first area, forming a protective layer on a bottom surface of the display panel to overlap the second area, and disposing an electronic module to overlap the first area. The forming the protective layer includes forming a preliminary protective layer including a first resin and a plurality of magnetic particles dispersed in the first resin, and curing the preliminary protective layer. The forming the preliminary protective layer includes applying magnetic force to the plurality of magnetic particles.

In an embodiment, the applying the magnetic force to the plurality of magnetic particles may include providing a magnetic substance on the display panel to overlap the second area.

In an embodiment, the forming the preliminary protective layer may further include, before the applying the magnetic force to the plurality of magnetic particles, applying the first resin onto the bottom surface of the display panel, and providing the plurality of magnetic particles to the first resin.

In an embodiment, the forming the preliminary protective layer may further include, after the applying the magnetic force to the plurality of magnetic particles, applying a second resin onto a bottom surface of the first resin, providing a plurality of lower magnetic particles the second resin, and applying magnetic force to the plurality of lower magnetic particles.

In an embodiment, the second area may include a second-1 area adjacent to the first area, and a second-2 area adjacent to the second-1 area and spaced apart from the first area, and the providing the plurality of magnetic particles to the first resin may further include providing the plurality of magnetic particles to overlap the second-2 area.

In an embodiment, the applying the magnetic force to the plurality of magnetic particles may include dispersing the plurality of magnetic particles to overlap the second-1 area and the second-2 area.

In an embodiment, the forming the preliminary protective layer may further include providing the plurality of magnetic particles to the bottom surface of the display panel before the applying the magnetic force to the plurality of magnetic particles, and may further include applying the first resin, which covers the plurality of magnetic particles, after the applying the magnetic force to the plurality of magnetic particles.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of an electronic device in an embodiment of the disclosure;

FIG. 2 is an exploded perspective view of an embodiment of an electronic device according to the inventive concept;

FIG. 3 is a cross-sectional view illustrating an embodiment of some components of an electronic device according to the inventive concept;

FIG. 4 is a cross-sectional view of an embodiment of a display panel;

FIG. 5 is a cross-sectional view of an embodiment of a portion of an electronic device according to the inventive concept;

FIG. 6 is an enlarged cross-sectional view of an embodiment of a portion of an electronic device according to the inventive concept;

FIGS. 7A and 7B are each a flowchart illustrating an embodiment of a method for manufacturing an electronic device according to the inventive concept;

FIGS. 8A to 8D are cross-sectional views illustrating an embodiment of some operations of a method for manufacturing an electronic device according to the inventive concept;

FIGS. 9A to 9C are cross-sectional views illustrating another embodiment of some operations of a method for manufacturing an electronic device according to the inventive concept; and

FIGS. 10A to 10C. are cross-sectional views illustrating another embodiment of some operations of a method for manufacturing an electronic device according to the inventive concept.

### DETAILED DESCRIPTION

In the disclosure, it will be understood that when an element (or region, layer, section, etc.) is referred to as being “on”, “connected to” or “coupled to” another element, it can be disposed directly on, connected or coupled to the other element or a third intervening elements may be disposed between the elements.

As used herein, the phrase “being directly disposed” may mean that there is no additional layer, film, region, plate or the like between a part such as a layer, film, region, plate or the like and another part. For example, “being directly disposed” may mean that two layers or two members are disposed with no additional member, such as an adhesive member, therebetween.

Like reference numbers or symbols refer to like elements throughout. In addition, in the drawings, the thickness, the ratio, and the dimension of elements are exaggerated for effective description of the technical contents. The term “and/or” includes one or more combinations that may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” and “has”, when used herein, specify the presence of stated features, numerals, steps, operations, elements, parts, or the combination thereof, but do not preclude the presence or addition of one or more other features, numerals, steps, operations, elements, parts, or the combination thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

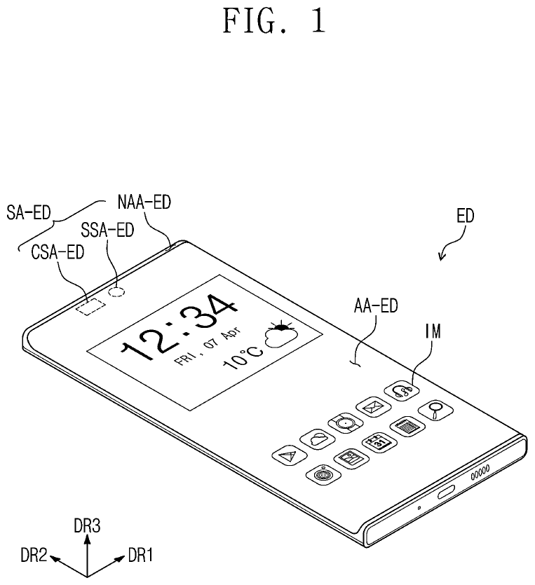

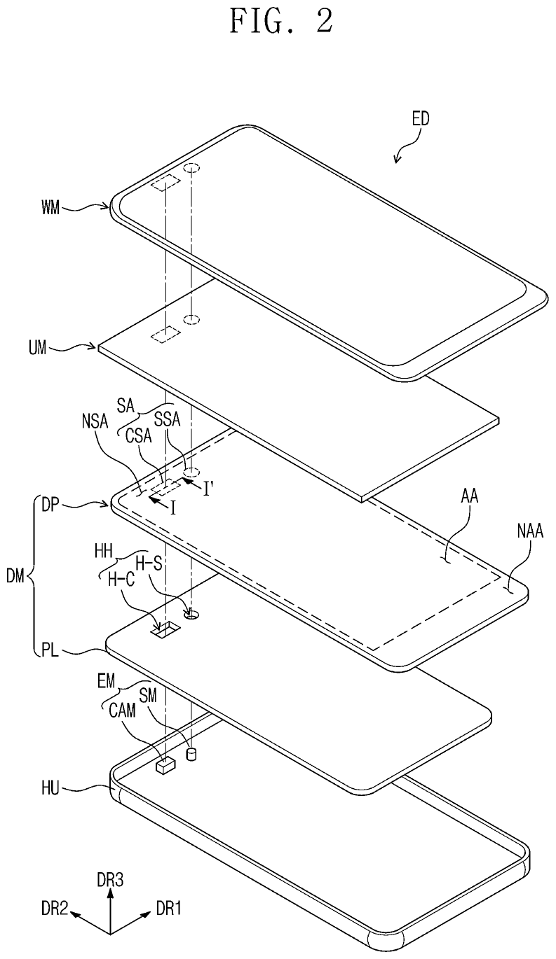

FIG. 1 is a perspective view of an embodiment of an electronic device ED according to the invention. FIG. 2 is an exploded perspective view of an embodiment of the electronic device ED according to the inventive concept.

The electronic device ED in an embodiment may be a device that is activated in response to an electrical signal. In an embodiment, the electronic device ED may be a mobile phone, a tablet computer, a vehicle navigation device, a game console, or a wearable device, for example, but is not limited thereto. FIG. 1 illustrates a mobile phone in an embodiment of the electronic device ED.

The electronic device ED may display an image IM through an active area AA-ED. The active area AA-ED may include a plane defined by a first direction DR1 and a second direction DR2. The active area AA-ED may further include a curved surface that is bent from at least one side of the plane defined by the first direction DR1 and the second direction DR2. The electronic device ED in an embodiment illustrated in FIG. 1 includes two curved surfaces that are bent from two side surfaces, respectively, of the plane defined by the first direction DR1 and the second direction DR2. However, the shape of the active area AA-ED is not limited thereto. In an embodiment, the active area AA-ED may include the plane alone, and the active area AA-ED may further include at least two curved surfaces, e.g., four curved surfaces, which are bent from four side surfaces of the plane, respectively, for example.

In FIG. 1 and the following drawings, first to third directions DR1 to DR3 are illustrated, and a direction indicated by each of the first direction DR1, the second direction DR2, and the third direction DR3 explained herein is a relative concept and may be changed to another direction.

In the disclosure, the first direction DR1 and the second direction DR2 may perpendicularly cross each other, and the third direction DR3 may be a normal direction to a plane defined by the first direction DR1 and the second direction DR2. In the disclosure, “in a plan view” may mean when viewed in a plan view defined by the first direction DR1 and the second direction DR2, and a thickness direction may mean the third direction DR3 that is a normal direction to a plane defined by the first direction DR1 and the second direction DR2.

A sensing area SA-ED may be defined in the electronic device ED. In an embodiment, FIG. 1 illustrates a camera sensing area CSA-ED and a sensor sensing area SSA-ED. However, the number of the sensing area SA-ED is not limited thereto, and a single sensing area SA-ED or three or more sensing areas SA-ED may be defined. In addition, the sensing area SA-ED may be defined in the active area AA-ED to be a portion of the active area AA-ED.

An electronic module EM may overlap the sensing area SA-ED. The electronic module EM may receive an external input delivered through the sensing area SA-ED, or provide an output through the sensing area SA-ED. In an embodiment, a camera module CAM may overlap the camera sensing area CSA-ED, and a sensor module SM may overlap the sensor sensing area SSA-ED, for example.

The electronic device ED may include the active area AA-ED and a peripheral area NAA-ED adjacent to the active area AA-ED. The active area AA-ED may correspond to an active area AA of a display panel DP to be described later, and the peripheral area NAA-ED may be a portion that corresponds to a peripheral area NAA of the display panel DP.

The peripheral area NAA-ED is an area that blocks an optical signal, and may be an area that is disposed outside the active area AA-ED to surround the active area AA-ED. In an embodiment, the peripheral area NAA-ED may be disposed not on a front surface but on a side surface of the electronic device ED. In an embodiment, the peripheral area NAA-ED may be omitted.

The electronic device ED in an embodiment includes a window WM, an upper member UM, a display module DM, a housing HU, and the electronic module EM.

The electronic device ED in an embodiment may include the window WM disposed on the display panel DP. The window WM provides an outer surface of the electronic device ED. The window WM may cover a front surface of the display panel DP, and protect the display panel DP from external impacts and scratches. The window WM may be coupled to the upper member UM through an adhesive layer.

The window WM may include an optically transparent insulating material. In an embodiment, the window WM may include a glass film or synthetic resin film as a base film, for example. The window WM may have a single-layer structure or a multilayer structure. In an embodiment, the window WM may include a plurality of plastic films coupled to each other through an adhesive, or may include a glass film and a plastic film coupled to each other through an adhesive, for example. The window WM may further include a functional layer such as an anti-fingerprint layer, a phase control layer or a hard coating layer, which is disposed on a transparent film.

In the electronic device ED in an embodiment, the upper member UM may be disposed below the window WM and above the display module DM. The upper member UM may include an anti-reflection layer and an input detecting sensor. The anti-reflection layer reduces the reflectance of external light. The input detecting sensor detects the user's external input. The upper member UM may further include an adhesive layer that couples the anti-reflection layer and the input detecting sensor to each other.

In the electronic device ED in an embodiment, the display module DM may be disposed below the upper member UM. The display module DM may include the display panel DP and a protective layer PL.

The display panel DP may include the active area AA, in which the image IM is displayed, and the peripheral area NAA adjacent to the active area AA. That is, the front surface of the display panel DP may include the active area AA and the peripheral area NAA. The active area AA may be a region that is activated in response to an electrical signal to generate the image IM displayed in the active area AA-ED of the electronic device ED.

The peripheral area NAA may be adjacent to the active area AA. The peripheral area NAA may surround the active area AA. A driving circuit or driving line for driving the active area AA, various signal lines or pads that supply electrical signals to the active area AA, electronic elements, or the like, are disposed in the peripheral area NAA.

The display panel DP includes a first area SA and a second area NSA. The active area AA of the display panel DP may include the first area SA and the second area NSA. The first area SA may be an area overlapping the electronic module EM, and the second area NSA may be an area surrounding at least a portion of the first area SA. The first area SA may correspond to the sensing area SA-ED of the electronic device ED. The second area NSA may be a portion, which corresponds to the remaining area except for the first area SA, of the active area AA of the display panel DP.

The first area SA may include a first signal transmission area CSA, which corresponds to the camera sensing area CSA-ED of the electronic device ED, and a second signal transmission area SSA which corresponds to the sensor sensing area SSA-ED of the electronic device ED. The camera module CAM may be disposed below the display panel DP to overlap the first signal transmission area CSA, and the sensor module SM may be disposed below the display panel DP to overlap the second signal transmission area SSA. Although not illustrated, a predetermine opening portion may be defined in one area of the first areas SA of the display panel DP as desired. That is, a portion of the display panel DP, which corresponds the one area of the first areas SA, may be penetrated.

FIG. 2 illustrates an example, in which the first area SA includes the first signal transmission area CSA and the second signal transmission area SSA, i.e., two transmission areas, but the number of the first area SA is not limited thereto. In an embodiment, one first area SA or three or more first areas SA may be defined in the display panel DP, for example. In addition, FIG. 2 illustrates an embodiment in which each of the first areas SA has a circular or polygonal shape. However, the shape of the first area SA is not limited thereto, and may be variously defined as desired.

The area of the first area SA may be less than the area of the second area NSA in a plan view. The second area NSA and the first area SA may have different transmittances. The transmittance of the first area SA may be greater than the transmittance of the second area NSA.

In the display panel DP in an embodiment, a portion of a driving circuit or driving line for driving a pixel disposed in the first area SA may be disposed in the peripheral area NAA or a portion, which is adjacent to the first area SA, of the second area NSA. Thus, a line density in the first area SA may be lower than a line density in the second area NSA. However, the disclosure is not limited thereto, and the line density in the first area SA may be substantially the same as the line density in the second area NSA.

The display panel DP may include a light-emitting element layer DP-ED (refer to FIG. 4) including an organic light-emitting element, a quantum dot light-emitting element, a micro light emitting element (e.g., micro light-emitting diode (“LED”)), a nano light-emitting element (e.g., nano LED), or the like. The light-emitting element layer DP-ED (refer to FIG. 4) may be a component that substantially generates an image.

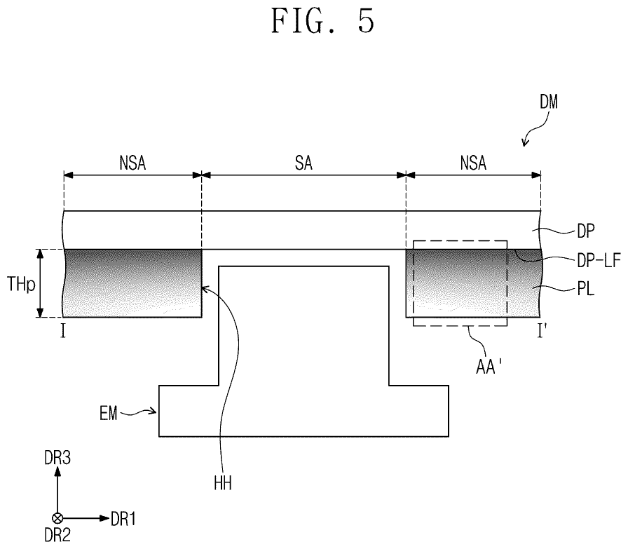

The protective layer PL may be disposed below the display panel DP. The protective layer PL may be a member that supports the display panel DP, absorbs an impact applied to the display panel DP, and performs a heat dissipation function to dissipate heat generated in components, e.g., the electronic module EM, which are disposed below the display panel DP. The protective layer PL will be described in detail with reference to FIG. 5 and the following drawings.

A hole HH may be defined in the protective layer PL. The hole HH may be defined in an area corresponding to the electronic module EM. The hole HH may be defined to overlap the first area SA of the display panel DP. In an embodiment, a single hole HH or a plurality of holes HH may be defined in the protective layer PL. The hole HH may include a sensor hole H-S and a camera hole H-C.

Although the hole HH is illustrated as being defined only in the protective layer PL in FIG. 2, the inventive concept is not limited thereto, and a predetermined opening portion may be additionally defined in the display panel DP as desired. The hole HH may overlap the electronic module EM. At least a portion of the electronic module EM may be inserted into the hole HH.

In the electronic device ED in an embodiment, the electronic module EM may be an electronic component that outputs or receives an optical signal. In an embodiment, the electronic module EM may include the camera module CAM and the sensor module SM, for example. The camera module CAM may receive external light through the camera sensing area CSA-ED to photograph an external image. In addition, the sensor module SM may be a sensor such as a proximity sensor or an infrared emitting sensor, which outputs or receives external light through the sensor sensing area SSA-ED.

In addition to the electronic module EM described above, the electronic device ED in an embodiment may further include a power module, a control module, a wireless communication module, an image input module, a sound input module, a sound output module, a memory, an external interface module, or the like. The electronic device ED may include a main circuit board, and the modules may be disposed (e.g., mounted) on the main circuit board or electrically connected to the main circuit board through a flexible circuit board. The power module may supply power desired for the overall operation of the electronic device ED. In an embodiment, the power module may include a typical battery device, for example.

Although not illustrated, the electronic device ED may include a flexible circuit board electrically connected to the display panel DP, and a main circuit board connected to the flexible circuit board. The flexible circuit board may be disposed on the peripheral area NAA of the display panel DP to be coupled to the display panel DP. The flexible circuit board may be connected to the main circuit board. The main circuit board may be one electronic component constituting the electronic module EM. A partial area, which is adjacent to the flexible circuit board, of the peripheral area NAA of the display panel DP may be provided as a bending area. The bending area may be bent with respect to a bending axis parallel to the first direction DR1. Due to the bending of the bending area, the flexible circuit board may overlap a portion of the display panel DP in a plan view.

The electronic device ED in an embodiment may include the display panel DP, and the housing HU disposed on the electronic module EM. The electronic module EM, the display panel DP, or the like may be accommodated in the housing HU. In the electronic device ED in an embodiment, the window WM and the housing HU may be coupled to constitute an outer appearance of the electronic device ED.

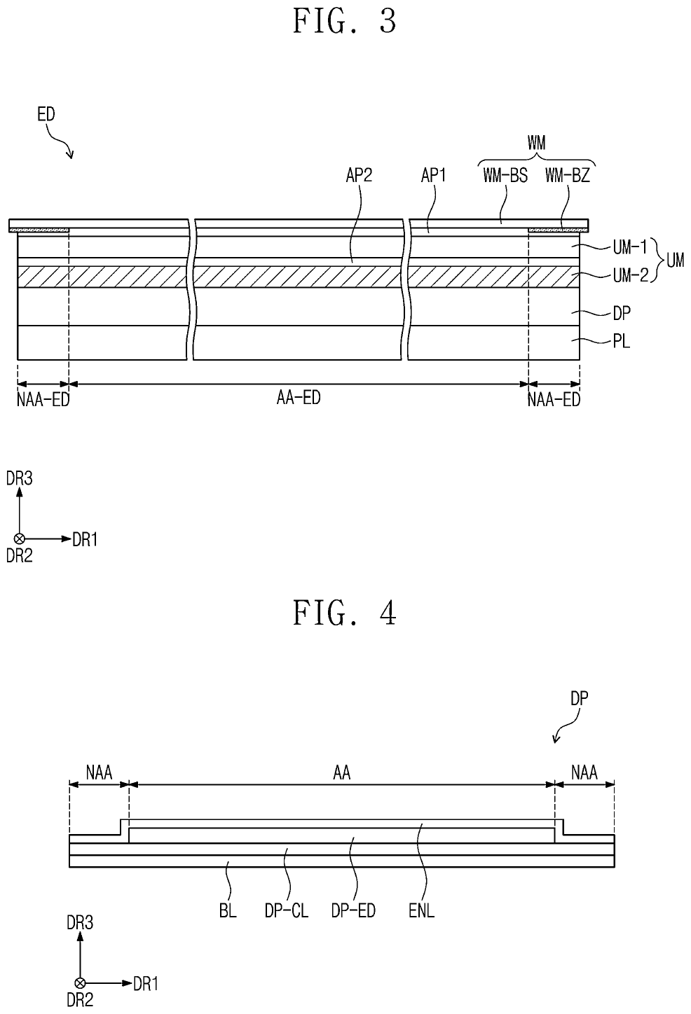

FIG. 3 is a cross-sectional view illustrating an embodiment of some components of an electronic device ED according to the inventive concept.

Referring to FIG. 3, the electronic device ED in an embodiment of the inventive concept may include a window WM, an upper member UM, a display panel DP, and a protective layer PL. The electronic device ED may include a front surface and a rear surface. The front surface of the electronic device ED may be defined on the window WM, and the rear surface of the electronic device ED may be defined on the protective layer PL.

In an embodiment, the window WM may cover a front surface of the display panel DP. The window WM may include a base substrate WM-BS and a bezel pattern WM-BZ. The base substrate WM-BS includes a transparent base layer such as a glass substrate or a transparent film. The bezel pattern WM-BZ may have a multilayer structure. The multilayer structure may include a colored layer and a black light-blocking layer. The colored layer and the black light-blocking layer may be formed through deposition, printing, and coating. In an alternative embodiment, the bezel pattern WM-BZ may be omitted on the window WM, and provided not on the base substrate WM-BS but on the upper member UM.

In an embodiment, the upper member UM includes an anti-reflection layer UM-1 and an input sensor UM-2. As illustrated in FIG. 3, the window WM and the anti-reflection layer UM-1 may be coupled to each other through a first adhesive layer AP1, and the input sensor UM-2 may be coupled through a second adhesive layer AP2. At least one of the first adhesive layer AP1 or the second adhesive layer AP2 may be omitted. In an embodiment, the second adhesive layer AP2 may be omitted, and the anti-reflection layer UM-1 may be disposed directly on the input sensor UM-2, for example.

The anti-reflection layer UM-1 may reduce external light reflectance. The anti-reflection layer UM-1 may include a phase retarder and/or a polarizer. The anti-reflection layer UM-1 may include a polarizing film or color filters. The color filters may have a predetermined arrangement. The arrangement of the color filters may be determined in consideration of emission colors of pixels included in the display panel DP. The anti-reflection layer UM-1 may further include a division layer adjacent to the color filters.

The input sensor UM-2 may include a plurality of sensing electrodes (not illustrated) for detecting an external input, trace lines (not illustrated) connected to the plurality of sensing electrodes, and an inorganic layer and/or an organic layer for insulating/protecting the plurality of sensing electrodes or the trace lines. The input sensor UM-2 may be a capacitance type sensor, but is not particularly limited.

The input sensor UM-2 may be formed directly on a thin-film encapsulation layer through a continuous process during manufacture of the display panel DP. However, the inventive concept is not limited thereto, and the input sensor UM-2 may be manufactured as a separate panel from the display panel DP and attached to the display panel DP through an adhesive layer.

The protective layer PL may be disposed below the display panel DP. The protective layer PL may be a member that supports the display panel DP and performs a heat dissipation function to dissipate heat generated in the display panel DP. The protective layer PL will be described in detail with reference to FIG. 5 and the following drawings.

FIG. 4 is a cross-sectional view of an embodiment of a display panel DP.

In an embodiment, the display panel DP includes a base layer BL, and a circuit layer DP-CL, a light-emitting element layer DP-ED, and an encapsulation layer ENL that are disposed on the base layer BL.

The base layer BL may include a plastic substrate, a glass substrate, a metal substrate, an organic/inorganic composite material substrate, or the like. In an embodiment, the base layer BL may include at least one polyimide layer, for example. The protective layer PL (refer to FIG. 3) described above may be disposed below the base layer BL.

The circuit layer DP-CL includes at least one insulation layer, semiconductor patterns, and conductive patterns. The insulation layer includes at least one inorganic layer and at least one organic layer. The semiconductor patterns and the conductive patterns may constitute signal lines, a pixel driving circuit, and a scan driving circuit. In addition, the circuit layer DP-CL may include a rear metal layer.

The light-emitting element layer DP-ED includes a display element, e.g., a light-emitting element. In an embodiment, the light-emitting element may be an organic light-emitting element, a quantum dot light-emitting element, a micro light-emitting element (e.g., micro LED), or a nano light-emitting element (e.g., nano LED). The light-emitting element layer DP-ED may further include an organic layer such as a pixel defining film.

The light-emitting element layer DP-ED may be disposed in an active area AA. A peripheral area NAA may be disposed outside the active area AA to surround the active area AA, and a light-emitting element may not be disposed in the peripheral area NAA.

The encapsulation layer ENL may be disposed on the light-emitting element layer DP-ED to cover the light-emitting element layer DP-ED. The encapsulation layer ENL may be disposed on the circuit layer DP-CL to seal the light-emitting element layer DP-ED. The encapsulation layer ENL may be a thin-film encapsulation layer including a plurality of organic thin films and inorganic thin films. The encapsulation layer ENL may include a thin-film encapsulation layer having a stacked structure of inorganic layer/organic layer/inorganic layer. The stacked structure of the encapsulation layer ENL is not particularly limited.

FIG. 5 is a cross-sectional view of an embodiment of a portion of an electronic device according to the inventive concept. FIG. 5 illustrates a cross section corresponding to cutting line I-I′ illustrated in FIG. 2.

Referring to FIG. 5, the electronic device in an embodiment of the inventive concept may include a display module DM and an electronic module EM.

A hole HH may be defined in the display module DM. The hole HH may be defined in a protective layer PL. The hole HH may be defined in an area corresponding to the electronic module EM. The hole HH may be defined to overlap a first area SA of the display panel DP. The electronic module EM in an embodiment is disposed to overlap the first area SA of the display panel DP. The hole HH of the protective layer PL may overlap the electronic module EM, and at least a portion of the electronic module EM may be inserted into the hole HH. In an embodiment, the electronic module EM may be the camera module CAM (refer to FIG. 2) including a lens, which is adjacent to a side of the display panel DP, and the lens of the camera module CAM (refer to FIG. 2) may be inserted into the hole HH, for example.

The display module DM in an embodiment may include the display panel DP, and the protective layer PL disposed below the display panel DP.

In the display module DM in an embodiment, the display panel DP may include a bottom surface DP-LF on which the protective layer PL in the form of a single layer is provided. The protective layer PL may be a member that supports the display panel DP, absorbs an impact applied to the display panel DP, and performs a heat dissipation function to dissipate heat generated in components, e.g., the electronic module EM, which are disposed below the display panel DP. In the electronic device ED (refer to FIG. 2) in an embodiment, as the protective layer PL in the form of a single layer performs all of the functions to absorb the impact and dissipate the heat, the electronic device ED (refer to FIG. 2) may be reduced in thickness and simplified in components, and process efficiency may increase during the manufacture of the electronic device ED (refer to FIG. 2).

The protective layer PL may not overlap the first area SA and may overlap a second area NSA in a plan view. The protective layer PL may correspond to the second area NSA of the display panel DP. The protective layer PL may be disposed below the display panel DP to overlap the second area NSA. The protective layer PL may be disposed directly below the display panel DP. The protective layer PL may contact the bottom surface DP-LF of the display panel DP. A separate adhesive member may not be disposed between the protective layer PL and the display panel DP.

The protective layer PL may have a thickness THp of about 50 micrometers (m) to about 300 m. In an embodiment, the thickness THp of the protective layer PL may be about 100 m to about 200 m, for example. The protective layer PL may have a viscosity of about 1,000 centipoises (cps) to about 100,000 cps. In an embodiment, the viscosity of the protective layer PL may be about 10,000 cps to about 50,000 cps, for example.

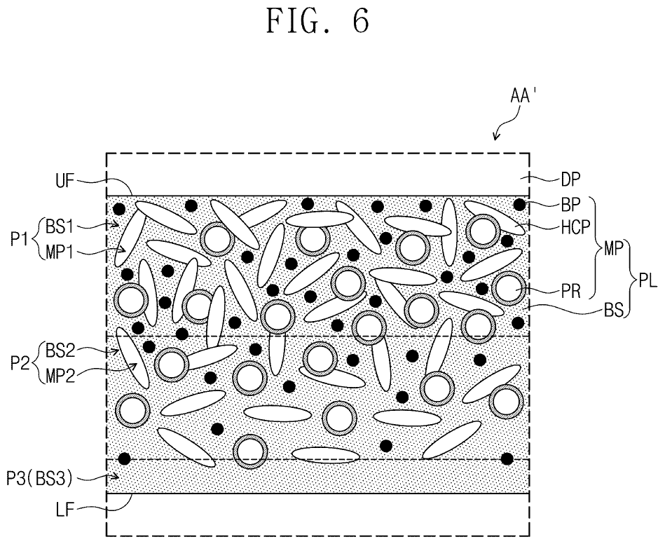

FIG. 6 is an enlarged cross-sectional view of an embodiment of a portion of an electronic device according to the inventive concept. FIG. 6 is an enlarged cross-sectional view illustrating area AA′ illustrated in FIG. 5. FIG. 6 is a cross-sectional view for illustrating in detail an embodiment of the protective layer PL according to the inventive concept.

Referring to FIG. 6, the protective layer PL may include a base resin BS and a magnetic particle MP dispersed in the base resin BS.

The protective layer PL may include the base resin BS. The base resin BS may include at least one of an acrylic resin, a urethane-based resin, a fluorine-based resin, an epoxy-based resin, a polyester-based resin, a polyamide-based resin, or a silicon-based resin. The base resin BS may include a curable resin. In an embodiment, the base resin BS may include a thermosetting resin or a photocurable resin, for example.

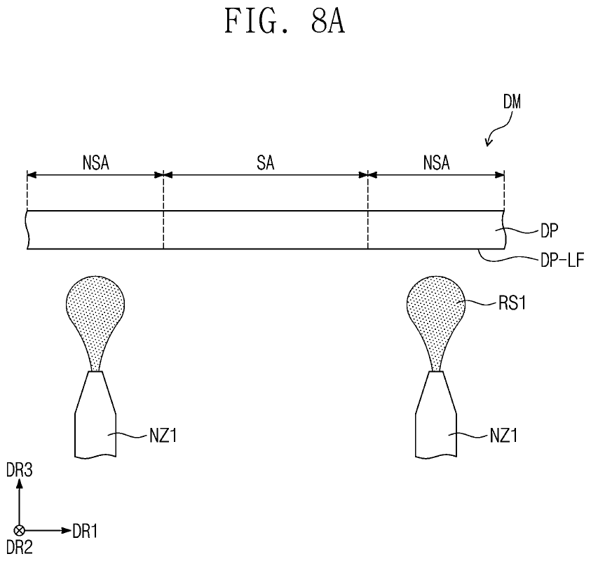

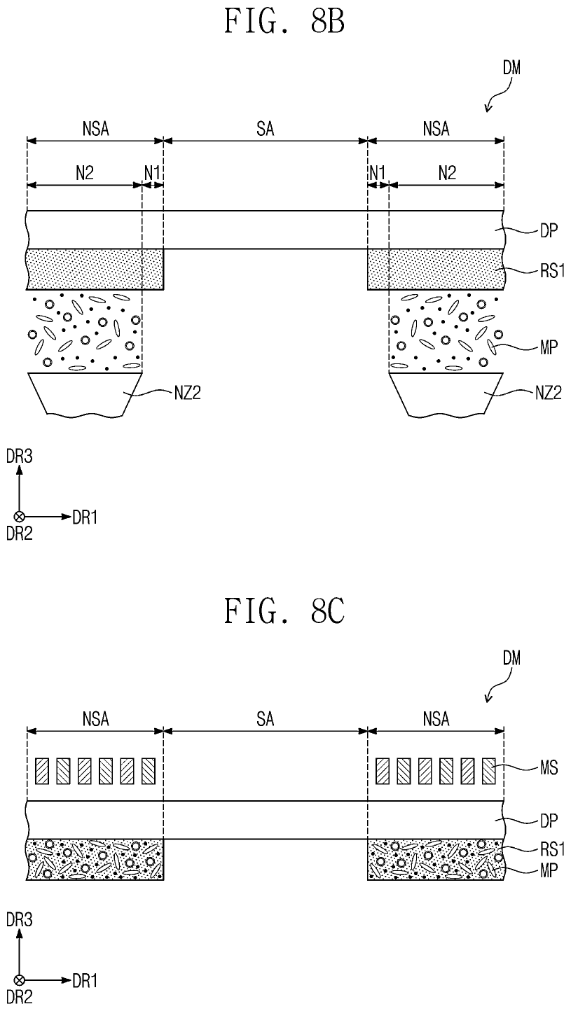

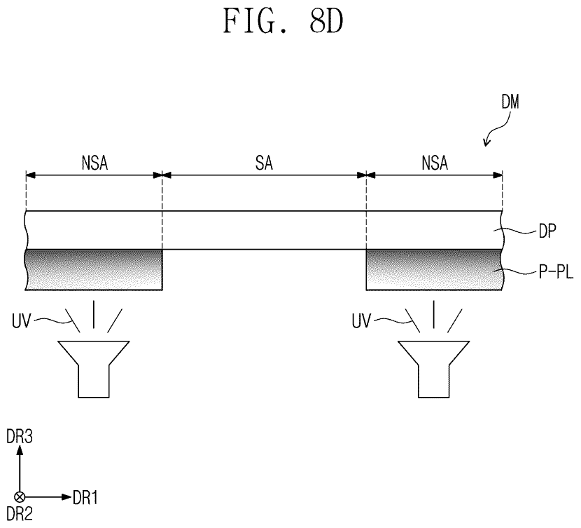

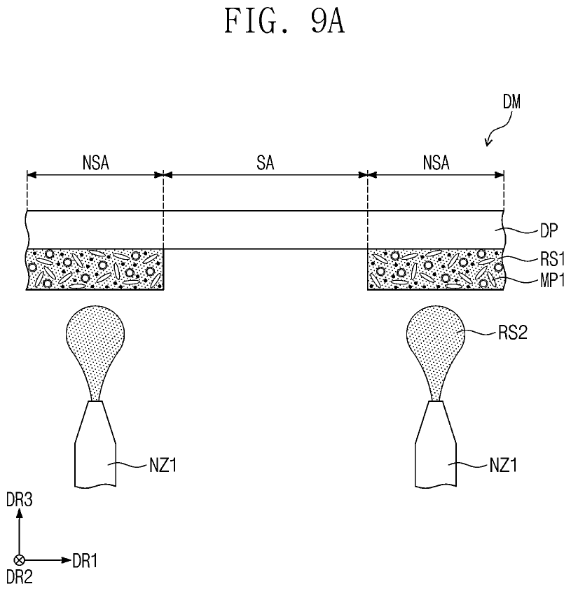

The protective layer PL includes the magnetic particle MP. In the disclosure, the magnetic particle MP may mean a material that has magnetic force due to magnetic fields of a magnetic substance MS (refer to FIG. 8C) used in a method for manufacturing the electronic device. The magnetic particle MP may include a material corresponding to a ferromagnetic substance. In an embodiment, the magnetic particle MP may include at least one kind of metal selected from the group including iron (Fe), manganese (Mn), nickel (Ni), and cobalt (Co), for example. In an alternative embodiment, the magnetic particle MP may include an alloy including at least two kinds of metals selected from the group including iron, manganese, nickel, and cobalt, for example. The magnetic particle MP may include or consist of a material corresponding to a ferromagnetic substance. In an alternative embodiment, the magnetic particle MP may include a material corresponding to a paramagnetic substance or a diamagnetic substance, and may have a shape in which an outer film is coated with the material corresponding to a ferromagnetic substance.

As the magnetic particle MP is included in the protective layer PL, the protective layer PL may perform a multi-function in the electronic device. The magnetic particle MP may include a shielding material BP, a heat dissipation material HCP, a support material PR. The magnetic particle MP may be used by mixing different kinds of materials or two or more kinds of materials having different sizes. As the magnetic particle MP includes the shielding material BP, the protective layer PL may have electromagnetic wave shielding properties. As the magnetic particle MP includes the heat dissipation material HCP, the protective layer PL may perform a heat dissipation function to dissipate heat generated in the display panel DP or the like. The heat dissipation material HCP may include at least one of a thermally conductive metal, a carbon-based heat dissipation material, or a thermally conductive polymer, for example. As the magnetic particle MP includes the support material PR, the protective layer PL may be improved in properties of protecting the display panel DP or the like from a physical impact applied from the outside of the display panel DP. However, the inventive concept is not limited thereto, and the protective layer PL may additionally perform other functions in the electronic device according to a material contained in the protective layer PL, properties such as thickness, or the like. In an embodiment, the magnetic particle MP may further include a light-blocking material, and the protective layer PL may further perform a light-blocking function to block light emitted from the display panel DP, for example.

The magnetic particle MP may have an average diameter of about 5 μm to about 200 μm. In an embodiment, each of the shielding material BP, the heat dissipation material HCP, and the support material PR may have an average diameter of about 5 μm to about 200 μm, for example. The magnetic particle MP may have a polydispersity distribution obtained by mixing a plurality of particles having a size distribution, which is substantially monodisperse, or a monodisperse distribution. When the average diameter of the magnetic particle MP is less than about 5 μm, it may be difficult to achieve the shielding, heat-dissipating, or supporting properties of the protective layer PL. When the average diameter of the magnetic particle MP is greater than about 200 μm, dispersion properties of the magnetic particle MP may be deteriorated in the protective layer PL to make it difficult to secure uniform thin-film properties.

A ratio of a weight of the magnetic particle MP to the total weight of the protective layer PL gradually increases from a bottom surface LF of the protective layer PL to a top surface UF of the protective layer PL. A density of the magnetic particle MP in the protective layer PL, which is close to the display panel DP, may be relatively high compared to a density of the magnetic particle MP in the protective layer PL, which is far from the display panel DP.

The protective layer PL may include a first portion P1 disposed below the display panel DP, and a second portion P2 disposed below the first portion P1. The protective layer PL may be arbitrarily divided into the first portion P1 adjacent to the display panel DP, and the second portion P2 far from the display panel DP. The first portion P1 may include a first base resin BS1 and a first magnetic particle MP1 dispersed in the first base resin BS1, and the second portion P2 may include a second base resin BS2 and a second magnetic particle MP2 dispersed in the second base resin BS2.

A ratio of a weight of the first magnetic particle MP1 to the total weight of the first portion P1 is relatively high compared to a ratio of a weight of the second magnetic particle MP2 to the total weight of the second portion P2. A density of the first magnetic particle MP1 in the first portion P1 may be higher than a density of the second magnetic particle MP2 in the second portion P2.

The first base resin BS1 of the first portion P1 may include the same material as that of the second base resin BS2 of the second portion P2. The first base resin BS1 of the first portion P1 and the second base resin BS2 of the second portion P2 may include or consist of the same material and formed through the same process at the same time. The first magnetic particle MP1 of the first portion P1 may include the same material as that of the second magnetic particle MP2 of the second portion P2. The first magnetic particle MP1 of the first portion P1 and the second magnetic particle MP2 of the second portion P2 may include or consist of the same material, but the density of the first magnetic particle MP1 in the first portion P1 may be higher than the density of the second magnetic particle MP2 in the second portion P2.

The protective layer PL may further include a third portion P3 disposed below the second portion P2. When the second magnetic particle MP2 is exposed to a bottom surface of the second portion P2, the third portion P3 may cover the exposed second magnetic particle MP2. The third portion P3 may include a third base resin BS3 and not include a separate magnetic particle. The third base resin BS3 may include the same material as that of the first base resin BS1 and the second base resin BS2. As the third portion P3 does not include a separate magnetic particle, a separate magnetic particle may not be exposed to the bottom surface LF of the protective layer PL including the third portion P3. As a separate magnetic particle is not exposed to the bottom surface LF of the protective layer PL, friction with another component provided in a process may be reduced during the manufacture of the electronic device in an embodiment, thereby increasing process efficiency.

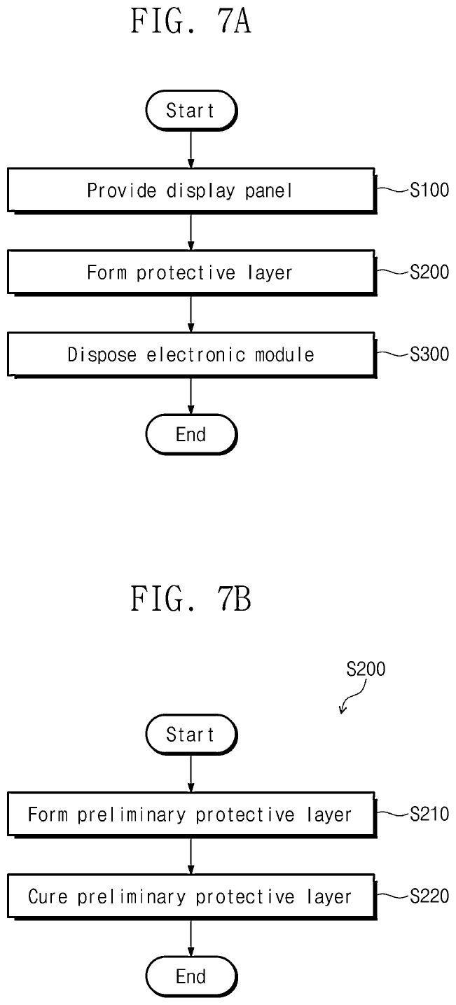

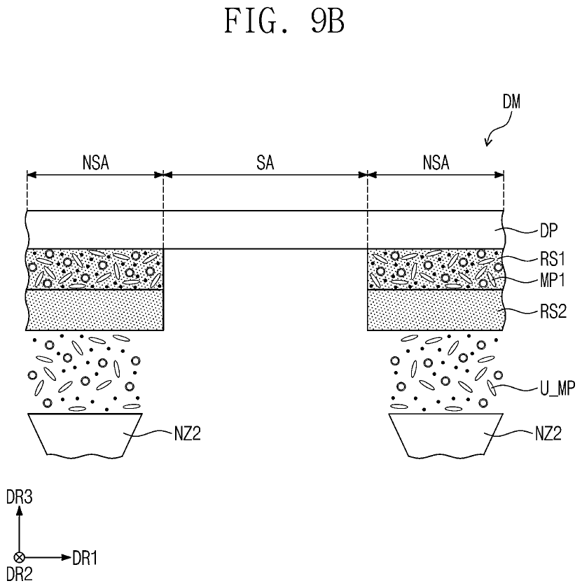

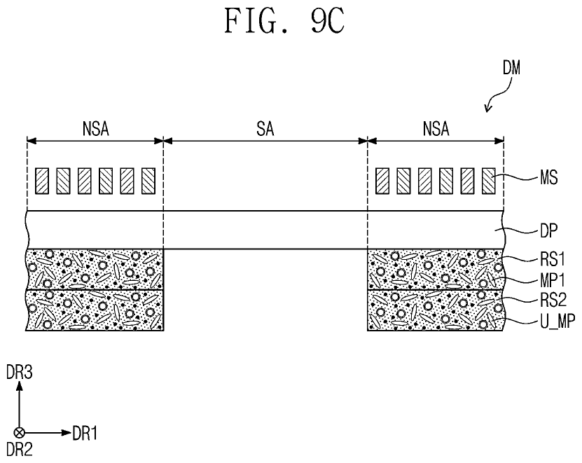

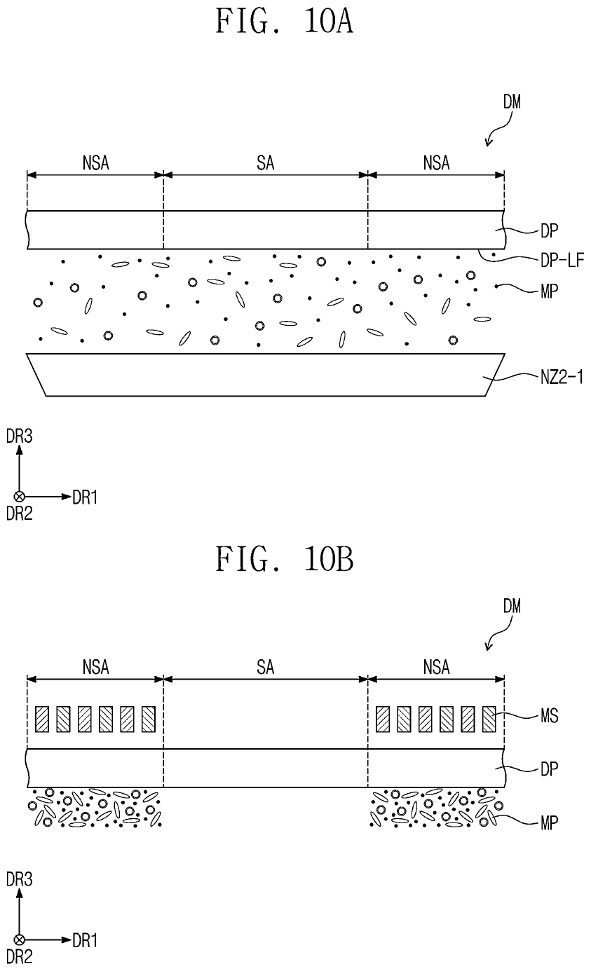

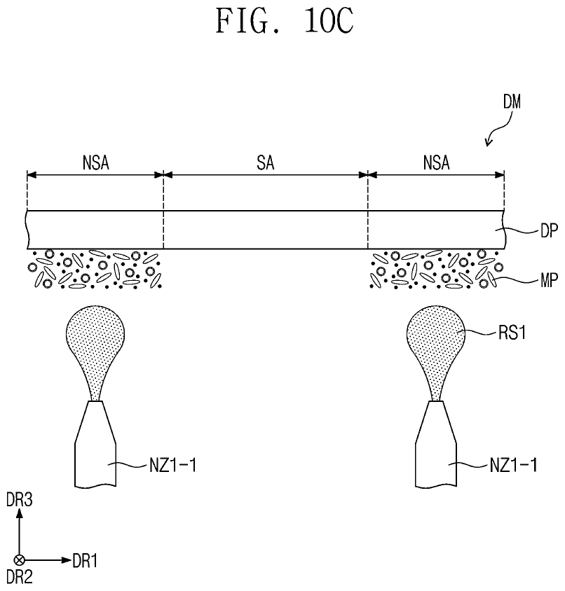

FIGS. 7A and 7B are flowcharts illustrating an embodiment of a method for manufacturing an electronic device. FIGS. 8A to 8D are cross-sectional views illustrating an embodiment of some operations of a method for manufacturing an electronic device according to the inventive concept. FIGS. 9A to 9C are cross-sectional views illustrating another embodiment of some operations of a method for manufacturing an electronic device according to the inventive concept. FIGS. 10A to 10C. are cross-sectional views illustrating another embodiment of some operations of a method for manufacturing an electronic device according to the inventive concept. The method for manufacturing the electronic device in an embodiment may be a method for manufacturing the electronic device ED in an embodiment described with reference to FIGS. 1 to 6. An embodiment provides a method for manufacturing an electronic device including a protective layer PL disposed below a display panel DP. Hereinafter, the method for manufacturing the electronic device in an embodiment will be described with reference to FIGS. 7A, 7B, 8A to 8D, 9A to 9C, and 10A to 10C. The same/similar components as/to those described above are denoted as the same/similar reference numbers or symbols, and detailed description thereof will be omitted.

Referring to FIG. 7A, the method for manufacturing the electronic device in an embodiment includes providing a display panel (S100), forming a protective layer (S200), and disposing an electronic module (S300). Referring to FIG. 7B, the forming of the protective layer (S200) of the method for manufacturing the electronic device in an embodiment includes forming a preliminary protective layer (S210) and curing the preliminary protective layer (S220).

FIGS. 8A to 8D, 9A to 9C, and 10A to 10C. are each a cross-sectional view schematically illustrating the forming of the protective layer on a bottom surface of the display panel to overlap a second area (S200) in the method for manufacturing the electronic device in another embodiment of the inventive concept. FIGS. 8A to 8D, 9A to 9C, and 10A to 10C. schematically illustrate manufacturing operations in the cross-sectional view corresponding to FIG. 5, which is described above.

FIGS. 8A to 8C each schematically illustrate forming a preliminary protective layer in an embodiment (S210) (refer to FIG. 7B). The forming of the preliminary protective layer in an embodiment (S210) (refer to FIG. 7B) may include applying a first resin, providing a magnetic particle to the applied first resin, and applying magnetic force to the magnetic particle. FIG. 8A schematically illustrates the applying of the first resin, FIG. 8B schematically illustrates the providing of the magnetic particle to the applied first resin, and FIG. 8C schematically illustrates the applying of the magnetic force to the magnetic particle. FIG. 8D schematically illustrates the curing of the preliminary protective layer including the first resin and the magnetic particle (S220) (refer to FIG. 7B).

Referring to FIG. 8A, a first resin RS1 may be applied onto a bottom surface DP-LF of a display panel DP through a first nozzle NZ1. The first resin RS1 may be provided to a portion corresponding to a second area NSA in the display panel DP. The first resin RS1 may be provided to the entirety of the second area NSA. The first resin RS1 may be provided to a portion other than the first area SA of the active area AA (refer to FIG. 2). In an embodiment, the first resin RS1 may be applied directly onto the bottom surface DP-LF of the display panel DP. Accordingly, a separate adhesive layer may not be desired between the display panel DP and the subsequently formed protective layer PL (refer to FIG. 5) to improve process properties of the electronic device.

To achieve a shape in which the protective layer PL (refer to FIG. 5) is specifically formed only in the second area NSA, the applying of the first resin RS1 may be performed through a predetermined process. The applying of the first resin RS1 may be performed through an inkjet process or a dispensing process, for example. As the applying of the first resin RS1 is performed through the inkjet or dispensing process, the first resin RS1 may be uniformly applied to correspond to the local second area NSA. Accordingly, process reliability of the electronic device may be improved.

The first resin RS1 may include a curable resin. The first resin RS1 may include at least one of an acrylic resin, a urethane-based resin, a fluorine-based resin, an epoxy-based resin, a polyester-based resin, a polyamide-based resin, or a silicon-based resin, each of which has curing properties. The first resin RS1 may be in the form of liquid before curing.

Referring to FIG. 8B, a magnetic particle MP may be provided to the first resin RS1 through a second nozzle NZ2. To achieve the shape in which the protective layer PL (refer to FIG. 5) is specifically formed only in the second area NSA, the magnetic particle MP may be provided only to a portion corresponding to the second area NSA. The magnetic particle MP may not be provided to a portion corresponding to the first area SA in the display panel DP.

The second area NSA of the display panel DP may include a second-1 area N1 adjacent to the first area SA, and a second-2 area N2 adjacent to the second-1 area N1 and spaced apart from the first area SA in a plan view. The magnetic particle MP may be provided to a portion corresponding to the second-2 area N2 of the second area NSA. The magnetic particle MP may not be provided to a portion overlapping the second-1 area N1, and may be provided only to a portion overlapping the second-2 area N2. The magnetic particle MP may be provided only to the second-2 area N2 to prevent the magnetic particle MP from being included in a portion corresponding to the electronic module EM (refer to FIG. 5) during the manufacturing of the electronic device.

Referring to FIG. 8C, magnetic force may be applied to the magnetic particle MP by a magnetic substance MS. The magnetic substance MS may be a magnet that is provided on the display panel DP to apply the magnetic force to the magnetic particle MP. Due to the magnetic force of the magnetic substance MS, the magnetic particle MP may move in a direction close to the display panel DP. As the magnetic particle MP moves in the direction close to the display panel DP, the magnetic particle MP may be dispersed in the first resin RS1 in the protective layer PL (refer to FIG. 5) in an embodiment in the third direction DR3. In addition, as the magnetic particle MP moves in the direction close to the display panel DP, a density of the magnetic particle MP in the protective layer PL (refer to FIG. 5) in an embodiment may gradually increase in the third direction DR3. In the disclosure, the magnetic substance MS corresponds to a means provided for magnetic movement of the magnetic particle MP, and does not correspond to a component included in the electronic device ED (refer to FIG. 2).

The magnetic substance MS may be provided to a portion corresponding to the second area NSA. The magnetic substance MS may be provided to a portion corresponding to each of the second-1 area N1 and the second-2 area N2. Due to the magnetic force of the magnetic substance MS, the magnetic particle MP may be dispersed in the entirety of portions corresponding not only to the second-1 area N1 but also to the second-2 area N2.

Referring to FIG. 8D, a preliminary protective layer P-PL including the first resin RS1 and the magnetic particle MP may be cured by heat or light. Light UV may be provided to the first resin RS1, which includes a curable resin, to cure the first resin RS1. The light UV may be ultraviolet light. In an embodiment, the light UV may be ultraviolet light having a centroid wavelength in a wavelength range of about 100 nanometers (nm) to about 400 nm, for example. The first resin RS1 may receive the ultraviolet light UV to be cured. The first resin RS1 may be cured by the light UV so that the protective layer PL (refer to FIG. 5) is formed.

The electronic device in an embodiment of the inventive concept may include the protective layer, which performs a multi-function, below the display panel to obtain the effects of reducing the thickness and simplifying components of the electronic device. As the display panel includes the light-emitting element, various side effects occur. To compensate the side effects, an electronic device according to the related art includes a plurality of members such as a shielding layer, a heat dissipation layer, a cushion layer, and a support layer, below the display panel. In contrast, in an embodiment of the inventive concept, the protective layer that performs the foregoing functions may be disposed to perform the functions that are performed by the plurality of layers according to the related art and also obtain the effects of reducing the thickness, simplifying components, and increasing the manufacture process efficiency. In the electronic device in an embodiment of the inventive concept, the magnetic particle may be included in the protective layer so that the predetermined shape of the electronic device is easily achieved, and the reliability of the manufacture process of the electronic device is improved. In the electronic device in an embodiment of the inventive concept, the base resin in the protective layer is formed through a dispensing process, and the magnetic particle in the protective layer is dispersed in the base resin due to magnetic force of an external magnetic substance. As the base resin and the magnetic particle in the protective layer are formed through prior and subsequent processes, respectively, not through a simultaneous process, the protective layer in an embodiment may be uniform to correspond to the local second area.

FIGS. 9A to 9C each schematically illustrate another embodiment of forming a preliminary protective layer (S210) (refer to FIG. 7B). The forming of the preliminary protective layer in another embodiment of the inventive concept (5210) (refer to FIG. 7B) may include applying a first resin, providing a magnetic particle to the applied first resin, applying magnetic force to the magnetic particle, applying a second resin below the first resin, providing a lower magnetic particle to the applied second resin, and applying magnetic force to the lower magnetic particle. That is, the forming of the preliminary protective layer in another embodiment may also include an operation in which the applying of the resin, the providing of the magnetic particle, and the applying of the magnetic force are repeated multiple times. FIGS. 9A to 9C illustrate the forming of the preliminary protective layer in an embodiment including an operation in which the applying of the resin, the providing of the magnetic particle, and the applying of the magnetic force are repeated twice. However, the disclosure is not limited thereto, and the applying of the resin, the providing of the magnetic particle, and the applying of the magnetic force may be repeated three or more times as desired.

FIG. 9A schematically illustrates the applying of the second resin below the first resin, FIG. 9B schematically illustrates the providing of the lower magnetic particle to the applied second resin, and FIG. 9C schematically illustrates the applying of the magnetic force to the second magnetic particle. The applying of the first resin, the providing of the first magnetic particle to the applied first resin, and the applying of the magnetic force to the first magnetic particle are the same as or similar to those illustrated with reference to FIGS. 8A to 8C, and the detailed description thereof will be omitted.

Referring to FIG. 9A, a second resin RS2 may be applied onto a bottom surface of a first resin RS1 through a first nozzle NZ1. The second resin RS2 may be provided to the entirety of the bottom surface of the first resin RS1 of a portion corresponding to a second area NSA. The second resin RS2 may include the same material as that of the first resin RS1. The applying of the second resin RS2 may be the same operation as the applying of the first resin RS1. The applying of the second resin RS2 may be performed through an inkjet process or a dispensing process, for example.

Referring to FIG. 9B, a lower magnetic particle U_MP may be provided to the second resin RS2 through a second nozzle NZ2. A portion corresponding to the second area NSA in the display panel DP may be provided with the lower magnetic particle U_MP. In the disclosure, a second magnetic particle may be also referred to as the “lower magnetic particle”.

Referring to FIG. 9C, magnetic force may be applied to the lower magnetic particle U_MP by a magnetic substance MS. Due to the magnetic force of the magnetic substance MS, the lower magnetic particle U_MP may move in a direction close to the display panel DP.

FIGS. 10A to 1OC. schematically illustrate another embodiment of forming a preliminary protective layer (S210) (refer to FIG. 7B). The forming of the preliminary protective layer in another embodiment of the inventive concept (S210) (refer to FIG. 7B) may include providing a magnetic particle to a bottom surface of a display panel, applying magnetic force to the magnetic particle, and applying a first resin that covers the magnetic particle. FIG. 10A schematically illustrates the providing of the magnetic particle to the bottom surface of the display panel, FIG. 10B schematically illustrates the applying of the magnetic force to the magnetic particle, and FIG. 10C illustrates the applying of the first resin that covers the magnetic particle.

Referring to FIG. 10A, a magnetic particle MP may be provided to a bottom surface DP-LF of a display panel DP through a second-1 nozzle NZ2-1. The magnetic particle MP may be provided not only to a portion corresponding to a second area NSA but also to a portion corresponding to a first area SA in the bottom surface DP-LF of the display panel DP.

Referring to FIG. 10B, magnetic force may be applied to the magnetic particle MP by a magnetic substance MS. The magnetic substance MS may be a magnet that is provided on the display panel DP to apply the magnetic force to the magnetic particle MP. Due to the magnetic force of the magnetic substance MS, the magnetic particle MP may move to the second area NSA. As the magnetic particle MP moves to the second area NSA, the magnetic particle MP may not be disposed in the portion corresponding to the first area SA. As the magnetic particle MP is disposed only in the portion corresponding to the second area NSA, the shape in which the protective layer PL (refer to FIG. 5) is specifically formed only in the second area NSA may be achieved.

Referring to FIG. 10C, a first resin RS1 may cover the magnetic particle MP and be applied onto a lower portion of the magnetic particle MP through a first-1 nozzle NZ1-1. The first resin RS1 may be provided to the entirety of the second area NSA. The applying of the first resin RS1 may be performed through an inkjet process or a dispensing process, for example.

As the protective layer below the display panel in the electronic device in the embodiment of the inventive concept includes the magnetic particle, the protective layer below the display panel may not be disposed in the transmission area, in which the electronic module is disposed, thereby improving the reliability of the electronic device. In addition, as the method for manufacturing the electronic device in the embodiment of the inventive concept uses the magnetic substance during the forming of the protective layer below the display panel, it may be easy to achieve the predetermined shape, in which the protective layer below the display panel is not disposed in the transmission area in which the electronic module is disposed, thereby improving the process efficiency of the manufacturing of the electronic device.

Although the embodiments of the invention have been described, it is understood that the invention should not be limited to these embodiments but various changes and modifications may be made by one ordinary skilled in the art within the spirit and scope of the invention as hereinafter claimed. Therefore, the technical scope of the inventive concept is not limited to the contents described in the detailed description of the specification, but should be determined by the claims.

What is claimed is:

1. An electronic device comprising:
a display panel comprising:
a first area; and
a second area adjacent to the first area;
an electronic module overlapping the first area and disposed below the display panel; and
a protective layer overlapping the second area and disposed below the display panel, the protective layer comprising:
a base resin and a plurality of magnetic particles dispersed in the base resin,
wherein a ratio of a weight of the plurality of magnetic particles to a total weight of the protective layer gradually increases from a bottom surface of the protective layer to a top surface of the protective layer.

2. The electronic device of claim 1, wherein the protective layer is disposed directly on a bottom surface of the display panel.

3. The electronic device of claim 1, wherein the protective layer has a thickness of about 100 micrometers to about 500 micrometers.

4. The electronic device of claim 1, wherein the base resin comprises a curable resin.

5. The electronic device of claim 1, wherein each of the plurality of magnetic particles comprises at least one of a heat dissipation material, a support material, or a shielding material.

6. The electronic device of claim 1, wherein the plurality of magnetic particles have an average diameter of about 5 micrometers to about 100 micrometers.

7. The electronic device of claim 1, wherein a hole overlapping the first area is defined in the protective layer,
wherein at least a portion of the electronic module is disposed inside the hole.

8. The electronic device of claim 1, wherein the protective layer comprises a first portion disposed below the display panel, and a second portion disposed below the first portion,
wherein the first portion comprises a first base resin and a plurality of first magnetic particles dispersed in the first base resin,
the second portion comprises a second base resin and a plurality of second magnetic particles dispersed in the second base resin, and
a ratio of a weight of the plurality of first magnetic particles to a total weight of the first portion is higher than a ratio of a weight of the plurality of second magnetic particles to a total weight of the second portion.

9. The electronic device of claim 8, wherein the first base resin comprises a same material as a material of the second base resin.

10. The electronic device of claim 8, wherein a density of the plurality of first magnetic particles is higher than a density of the plurality of second magnetic particles.

11. The electronic device of claim 8, wherein the protective layer further comprises a third portion disposed below the second portion,
wherein the third portion comprises a third base resin and covers the plurality of second magnetic particles.

12. The electronic device of claim 11, wherein the third base resin comprises a same material as a material of the first base resin and the second base resin.

13. An electronic device comprising:
a display panel comprising:
a first area; and
a second area adjacent to the first area; and
a protective layer overlapping the second area and disposed below the display panel, the protective layer comprising:
a first portion disposed below the display panel, the first portion comprising a first base resin and a plurality of first magnetic particles dispersed in the first base resin;
a second portion disposed below the first portion, the second portion comprising a second base resin and a plurality of second magnetic particles dispersed in the second base resin,
wherein a ratio of a weight of the plurality of first magnetic particles to a total weight of the first portion is higher than a ratio of a weight of the plurality of second magnetic particles to a total weight of the second portion.

14. A method for manufacturing an electronic device, the method comprising:
providing a display panel comprising a first area and a second area adjacent to the first area;
forming a protective layer on a bottom surface of the display panel to overlap the second area; and
disposing an electronic module to overlap the first area,
wherein the forming the protective layer comprises:
forming a preliminary protective layer comprising a first resin and a plurality of magnetic particles dispersed in the first resin; and
curing the preliminary protective layer,
wherein the forming the preliminary protective layer comprises applying magnetic force to the plurality of magnetic particles.

15. The method of claim 14, wherein the applying the magnetic force to the plurality of magnetic particles comprises providing a magnetic substance on the display panel to overlap the second area.

16. The method of claim 14, wherein the forming the preliminary protective layer further comprises, before the applying the magnetic force to the plurality of magnetic particles:
applying the first resin onto the bottom surface of the display panel; and
providing the plurality of magnetic particles to the first resin.

17. The method of claim 16, wherein the forming the preliminary protective layer further comprises, after the applying the magnetic force to the plurality of magnetic particles:
applying a second resin onto a bottom surface of the first resin;
providing a plurality of lower magnetic particles to the second resin; and
applying magnetic force to the plurality of lower magnetic particles.

18. The method of claim 16, wherein the second area comprises a second-1 area adjacent to the first area, and a second-2 area adjacent to the second-1 area and spaced apart from the first area,
wherein the providing the plurality of magnetic particles to the first resin comprises providing the plurality of magnetic particles to overlap the second-2 area.

19. The method of claim 18, wherein the applying the magnetic force to the plurality of magnetic particles comprises dispersing the plurality of magnetic particles to overlap the second-1 area and the second-2 area.

20. The method of claim 14, wherein the forming the preliminary protective layer further comprises:
providing the plurality of magnetic particles to the bottom surface of the display panel before the applying the magnetic force to the plurality of magnetic particles; and
applying the first resin configured to cover the plurality of magnetic particles, after the applying the magnetic force to the plurality of magnetic particles.
